(19) United States
(12) Patent Application Publication
(10) Pub. No.: US 2025/0098172 A1
(43) Pub. Date: Mar. 20, 2025

(54) SEMICONDUCTOR MEMORY DEVICE, METHOD FOR FABRICATING THE SAME AND ELECTRONIC SYSTEM INCLUDING THE SAME

(71) Applicant: Samsung Electronics Co., Ltd., Suwon-si (KR)

(72) Inventors: Hak Seon KIM, Suwon-si (KR); Kang Oh YUN, Suwon-si (KR); Dong Jin LEE, Suwon-si (KR); Jae Duk LEE, Suwon-si (KR)

(73) Assignee: Samsung Electronics Co., Ltd., Suwon-si (KR)

(21) Appl. No.: 18/773,994

(22) Filed: Jul. 16, 2024

(30) Foreign Application Priority Data
Sep. 15, 2023 (KR) 10-2023-0123336

(51) Int. Cl. H10B 43/40; H01L 23/00; H01L 25/065; H01L 25/18; H10B 43/27; H10B 80/00

(52) U.S. Cl. CPC H10B 43/40; H01L 24/08; H01L 25/0657; H01L 25/18; H10B 43/27; H10B 80/00; H01L 2224/08145; H01L 2924/1205; H01L 2924/1431; H01L 2924/14511

(57) ABSTRACT

A semiconductor memory device includes a peripheral circuit structure; and a cell structure including a cell substrate and a gate electrode, on the peripheral circuit structure. The peripheral circuit structure includes a peripheral circuit board including a first surface facing the cell structure and a second surface opposite to the first surface, a first circuit element on the first surface of the peripheral circuit board, a first wiring line electrically connected to the first circuit element in a first interlayer insulating layer, a capacitor dielectric layer covering the second surface of the peripheral circuit board, a first capacitor electrode in the capacitor dielectric layer, a second capacitor electrode spaced apart from the first capacitor electrode in the capacitor dielectric layer, and a first connection via electrically connecting the first capacitor electrode with the first wiring line by passing through the peripheral circuit board.

### CROSS-REFERENCE TO RELATED APPLICATION

This application claims priority from Korean Patent Application No. 10-2023-0123336 filed on Sep. 15, 2023, in the Korean Intellectual Property Office and all the benefits accruing therefrom under 35 U.S.C. § 119, the contents of which in its entirety are herein incorporated by reference.

### BACKGROUND

Various example embodiments relate to a semiconductor memory device, a method for fabricating the same, and/or an electronic system including the same.

As a semiconductor memory device capable of storing data of high capacity is required or expected in an electronic system, methods capable of increasing data storage capacity of a semiconductor memory device have been studied. As one of methods capable of increasing data storage capacity of a semiconductor memory device, a semiconductor memory device including memory cells, which are arranged three-dimensionally instead of memory cells that are two-dimensionally, has been suggested.

### BRIEF SUMMARY

Various example embodiments may provide a semiconductor memory device having a reduced size.

Alternatively or additionally, various example embodiments may provide an electronic system including a semiconductor memory device having a reduced size.

Alternatively or additionally, various example embodiments may provide a method for fabricating a semiconductor memory device having a reduced size.

Example embodiments are not limited to those mentioned above and additional objects of the present disclosure, which are not mentioned herein, will be clearly understood by those skilled in the art from the following description.

According to some example embodiments, a semiconductor memory device includes a peripheral circuit structure; and a cell structure on the peripheral circuit structure and including a cell substrate and a gate electrode. The peripheral circuit structure includes a peripheral circuit board including a first surface facing the cell structure and a second surface opposite to the first surface, a first circuit element on the first surface of the peripheral circuit board, a first interlayer insulating layer covering the first surface of the peripheral circuit board, a first wiring line electrically connected to the first circuit element in the first interlayer insulating layer, a capacitor dielectric layer covering the second surface of the peripheral circuit board, a first capacitor electrode in the capacitor dielectric layer, a second capacitor electrode spaced apart from the first capacitor electrode in the capacitor dielectric layer, and a first connection via electrically connecting the first capacitor electrode with the first wiring line by passing through the peripheral circuit board.

Alternatively or additionally according to some example embodiments, a semiconductor memory device includes a first peripheral circuit structure; and a cell structure stacked on the first peripheral circuit structure and including memory cells. The first peripheral circuit structure includes a first peripheral circuit board including a first surface facing the cell structure and a second surface opposite to the first surface, a first circuit element on the first surface of the first peripheral circuit board, and a first capacitor on the second surface of the first peripheral circuit board.

Alternatively or additionally according to some example embodiments, an electronic system includes a main board; a semiconductor memory device on the main board and including a peripheral circuit structure and a cell structure, the cell structure being stacked on the peripheral circuit structure; and a controller electrically connected to the semiconductor memory device on the main board. The peripheral circuit structure includes a peripheral circuit board including a first surface facing the cell structure and a second surface opposite to the first surface, a first circuit element on the first surface of the peripheral circuit board, and a capacitor configured to provide an operating voltage to the first circuit element on the second surface of the peripheral circuit board.

Alternatively or additionally according to some example embodiments, a method for fabricating a semiconductor memory device includes forming a pre-peripheral circuit structure including a peripheral circuit board having first and second surfaces opposite to each other, a circuit element on the first surface of the peripheral circuit board, a connection via passing through a portion of the peripheral circuit board, and a first wiring line electrically connected to the circuit element or the connection via; bonding pre-peripheral circuit structure onto a semiconductor chip; exposing a portion of the connection via by etching a portion of the second surface of the peripheral circuit board; and forming a capacitor electrically connected to the connection via on the second surface of the peripheral circuit board.

### BRIEF DESCRIPTION OF THE DRAWINGS

The above and other aspects and features will become more apparent by describing in detail various example embodiments thereof with reference to the attached drawings, in which:

FIG. 1 is an exemplary block diagram illustrating a semiconductor memory device according to some example embodiments;

FIG. 2 is an exemplary circuit diagram illustrating a semiconductor memory device according to some example embodiments;

FIG. 3 is a schematic perspective view illustrating a semiconductor memory device according to some example embodiments;

FIG. 4 is a cross-sectional view illustrating a semiconductor memory device according to some example embodiments;

FIG. 5 is an enlarged view illustrating an area Q of FIG. 4;

FIG. 6 is an enlarged view illustrating an area S1 of FIG. 4;

FIG. 7 is an enlarged view illustrating an area A of FIG. 4;

FIGS. 8 to 10 are views illustrating a capacitor electrode of a semiconductor memory device according to some example embodiments;

FIG. 11 are views illustrating a semiconductor memory device according to some example embodiments;

FIG. 12 are views illustrating a semiconductor memory device according to some example embodiments;

FIG. 13 is a cross-sectional view illustrating a semiconductor memory device according to some example embodiments;

FIG. 14 is an enlarged view illustrating an area S1 of FIG. 13;

FIG. 15 is a cross-sectional view illustrating a semiconductor memory device according to some example embodiments;

FIG. 16 is an enlarged view illustrating an area B of FIG. 15;

FIG. 17 is an enlarged view illustrating an area C of FIG. 15;

FIG. 18 is an enlarged view illustrating an area D of FIG. 15;

FIG. 19 is a schematic perspective view illustrating a semiconductor memory device according to some example embodiments;

FIGS. 20 to 22 are views illustrating intermediate steps to describe a method for fabricating a semiconductor memory device according to some example embodiments;

FIG. 23 is an exemplary block diagram illustrating an electronic system according to some example embodiments;

FIG. 24 is an exemplary perspective view illustrating an electronic system according to some example embodiments;

FIG. 25 is a schematic cross-sectional view taken along line I-I of FIG. 24; and

FIGS. 26 to 28 are views illustrating a semiconductor memory device according to some example embodiments.

### DETAILED DESCRIPTION OF VARIOUS EXAMPLE EMBODIMENTS

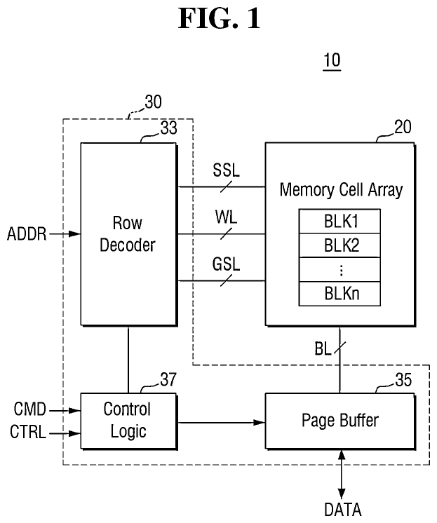

FIG. 1 is an exemplary block diagram illustrating a semiconductor memory device according to some example embodiments.

Referring to FIG. 1, a semiconductor memory device 10 according to some example embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells such as but not limited to one or more of main cells, dummy cells, and redundancy cells. The memory cell array 20 may be connected to the peripheral circuit 30 through a bit line BL, a word line WL, at least one string selection line SSL, and at least one ground selection line GSL. In detail, the memory cell blocks BLK1 to BLKn may be connected to a row decoder 33 through the word line WL, the string selection line SSL and the ground selection line GSL. In addition, the memory cell blocks BLK1 to BLKn may be connected to a page buffer 35 through the bit line BL.

The peripheral circuit 30 may receive one or more of an address ADDR, a command CMD, and a control signal CTRL from the outside of the semiconductor memory device 10, and may transmit and receive data DATA to and/or from an external device of the semiconductor memory device 10. The peripheral circuit 30 may include a control logic 37, the row decoder 33, and the page buffer 35. Although not shown, the peripheral circuit 30 may further include various sub-circuits such as one or more of an input/output circuit, a voltage generating circuit for generating various voltages required for or used for an operation of the semiconductor memory device 10, and an error correction circuit for correcting an error of the data DATA read from the memory cell array 20.

The control logic 37 may be connected to the row decoder 33, the input/output circuit, and the voltage generating circuit. The control logic 37 may control the overall operation of the semiconductor memory device 10. The control logic 37 may generate various internal control signals used in the semiconductor memory device 10 in response to the control signal CTRL. For example, the control logic 37 may adjust a voltage level provided to the word line WL and/or to the bit line BL when a memory operation such as a program operation and/or an erase operation is performed.

The row decoder 33 may select at least one of the plurality of memory cell blocks BLK1 to BLKn in response to the address ADDR, and may select at least one word line WL, at least one string selection line SSL, and at least one ground selection line GSL of the selected memory cell blocks BLK1 to BLKn. In addition, the row decoder 33 may transmit a voltage for performing the memory operation to the word line WL of the selected memory cell blocks BLK1 to BLKn.

The page buffer 35 may be connected to the memory cell array 20 through the bit line BL. The page buffer 35 may operate as a write driver and/or as a sense amplifier. In detail, when a program operation is performed, the page buffer 35 may operate as a write driver to apply a voltage according to the data DATA to be stored in the memory cell array 20, to the bit line BL. Meanwhile, when a read operation is performed, the page buffer 35 may operate as a sense amplifier to sense the data DATA stored in the memory cell array 20.

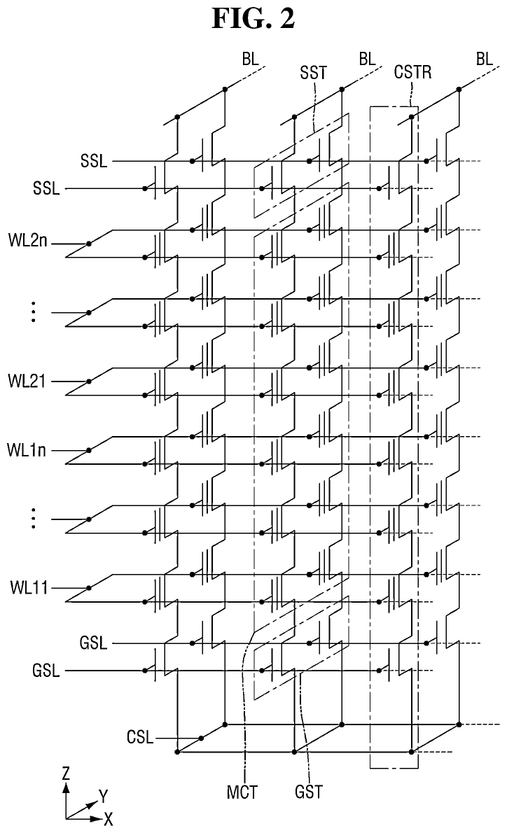

FIG. 2 is an example circuit diagram illustrating a semiconductor memory device according to some example embodiments.

Referring to FIG. 2, the memory cell array (e.g., 20 of FIG. 1) of the semiconductor memory device according to some example embodiments includes a common source line CSL, a plurality of bit lines BL, and a plurality of cell strings CSTR.

The plurality of bit lines BL may be arranged two-dimensionally on a plane that includes a first direction X and a second direction Y. For example, the bit lines BL may be extended in the second direction Y, and may be arranged along the first direction X by being spaced apart from each other. The plurality of cell strings CSTR may be respectively connected to the respective bit lines BL in parallel. The cell strings CSTR may be commonly connected to the common source line CSL. For example, the plurality of cell strings CSTR may be disposed between the bit lines BL and the common source line CSL.

Each of the cell strings CSTR may include a ground selection transistor GST connected to the common source line CSL, a string selection transistor SST connected to the bit line BL, and a plurality of memory cell transistors MCT disposed between the ground selection transistor GST and the string selection transistor SST. Each of the memory cell transistors MCT may include a data storage element. The ground selection transistor GST, the string selection transistor SST, and the memory cell transistors MCT may be connected in series.

The common source line CSL may be commonly connected to sources of the ground selection transistors GST. In addition, the ground selection line GSL, a plurality of word lines WL11 to WL1n and WL21 to WL2n and the string selection line SSL may be disposed between the common source line CSL and the bit line BL. Here, “n” describing the number of word lines may or may not be the same value as “n” referred to in FIG. 1 to describe the number of blocks. The ground selection line GSL may be used as a gate electrode of the ground selection transistor GST, the word lines WL11 to WL1n, and WL21 to WL2n may be used as gate electrodes of the memory cell transistors MCT, and the string selection line SSL may be used as a gate electrode of the string selection transistor SST.

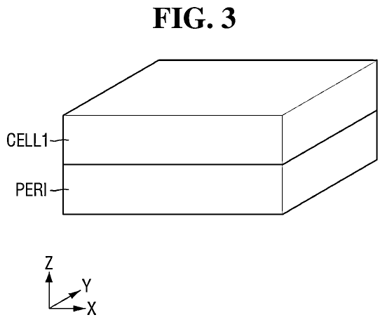

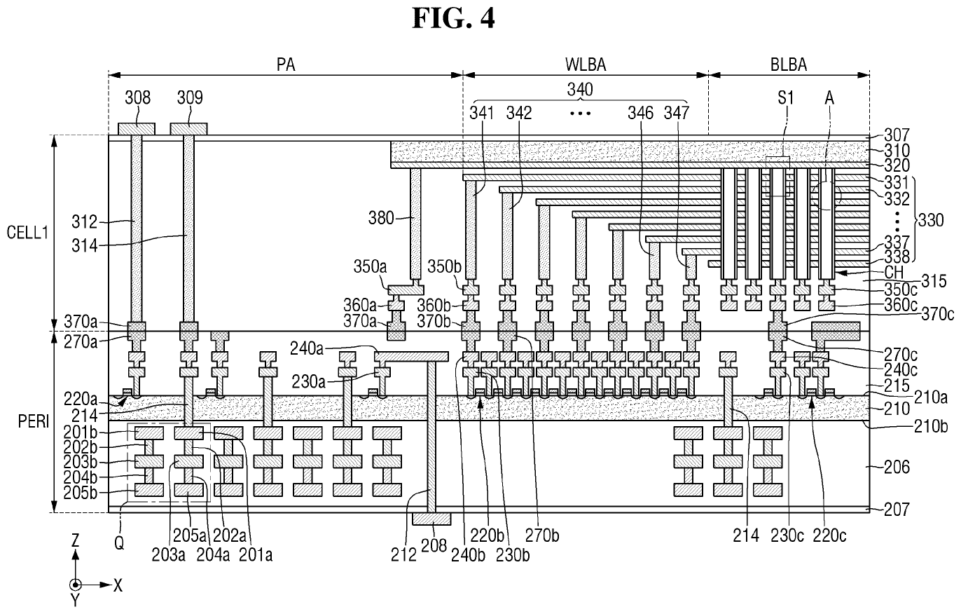

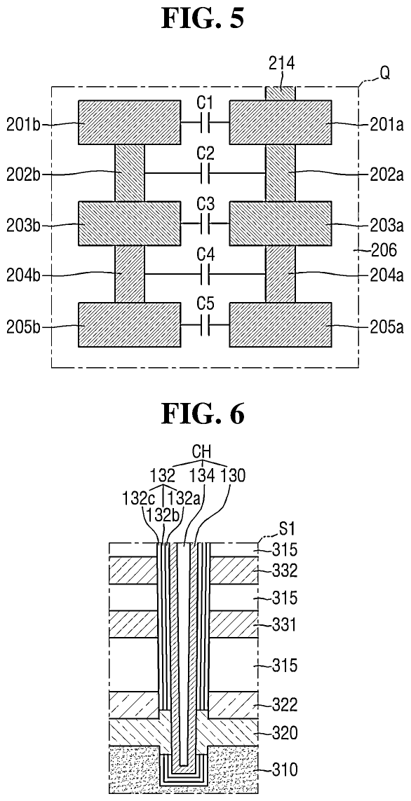

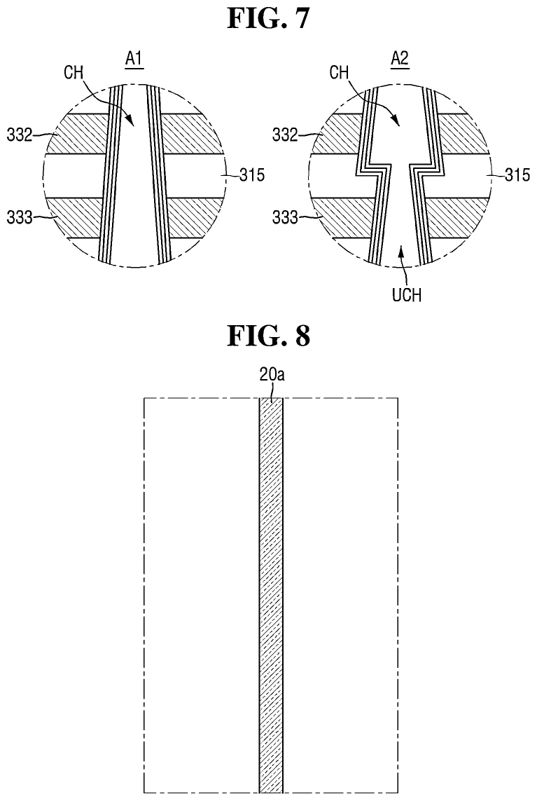

FIG. 3 is a schematic perspective view illustrating a semiconductor memory device according to some example embodiments. FIG. 4 is a cross-sectional view illustrating a semiconductor memory device according to some example embodiments. FIG. 5 is an enlarged view illustrating an area Q of FIG. 4. FIG. 6 is an enlarged view illustrating an area S1 of FIG. 4. FIG. 7 is an enlarged view illustrating an area A of FIG. 4.

Referring to FIGS. 3 and 4, the semiconductor memory device according to some example embodiments may include a peripheral circuit structure PERI and a first cell structure CELL1. The peripheral circuit structure PERI and the first cell structure CELL1 are stacked in a third direction Z. The first cell structure CELL1 is disposed above the peripheral circuit structure PERI. Hereinafter, an upper portion, an upper surface, a lower portion and a lower surface of the first cell structure CELL1 are defined based on an opposite direction of the third direction Z, and an upper portion, an upper surface, a lower portion and a lower surface of the peripheral circuit structure PERI are defined based on the third direction Z.

The semiconductor memory device according to some example embodiments may have a chip-to-chip (C2C) structure. The C2C structure may indicate that an upper chip including the first cell structure CELL1 is manufactured on a first wafer (for example, a first cell substrate 310), a lower chip including the peripheral circuit structure PERI is manufactured on a second wafer (for example, a peripheral circuit board 210 or peripheral circuit structure) different from the first wafer, and then the upper chip and the lower chip are connected to each other by a bonding method. In some example embodiments, either or both of the first wafer and the second wafer may or may not be diced and singulated prior to bonding, for example with a wafer-to-wafer (W2 W), a die-to-wafer (D2 W), or a die-to-die (D2D) bonding; example embodiments are not limited thereto.

For example, the bonding method may indicate a method for electrically connecting first bonding metals 270a, 270b and 270c formed on an uppermost metal layer of the lower chip with first bonding metals 370a, 370b and 370c formed on an uppermost metal layer of the upper chip. For example, when the first bonding metals 270a, 270b and 270c and the first bonding metals 370a, 370b and 370c are formed of copper (Cu), the bonding method may be a Cu—Cu bonding method. However, this is only by way of example, and the first bonding metals 270a, 270b and 270c and the first bonding metals 370a, 370b and 370c may be formed of various other metals such as aluminum (Al) and/or tungsten (W).

Each of the peripheral circuit structure PERI and the first cell structure CELL may include a bit line bonding area BLBA, a word line bonding area WLBA and an external pad bonding area PA. The word line bonding area WLBA may be defined around the bit line bonding area BLBA. For example, the word line bonding area WLBA may surround the bit line bonding area BLBA. The external pad bonding area PA may be defined outside the word line bonding area WLBA. For example, the external pad bonding area PA may surround the word line bonding area WLBA when viewed in a plan view.

The peripheral circuit structure PERI includes a peripheral circuit board 210, a plurality of first capacitor electrodes 201a, 202a, 203a, 204a and 205a, a plurality of second capacitor electrodes 201b, 202b, 203b, 204b and 205b, a capacitor dielectric layer 206, a first insulating film 207, a first input/output pad 208, a first input/output contact plug 212, a connection via 214, a first interlayer insulating layer 215, a plurality of circuit elements 220a, 220b and 220c, first wiring lines 230a, 230b and 230c, second wiring lines 240a, 240b and 240c, and first bonding metals 270a, 270b and 270c.

The peripheral circuit board 210 may include a first surface 210a and a second surface 210b, which are opposite to each other. The first surface 210a may be referred to as a front side, and the second surface 210b may be referred to as a back side; example embodiments are not limited thereto. The first surface 210a may face the first cell structure CELL1.

The circuit elements 220a, 220b and 220c are disposed on the first surface 210a of the peripheral circuit board 210. The circuit elements 220a, 220b and 220c may constitute or be included in a peripheral circuit (e.g., 30 of FIG. 1) for controlling the operation of the semiconductor memory device. For example, the circuit elements 220a, 220b and 220c may include a control logic (e.g., 37 of FIG. 1), a row decoder (e.g., 33 of FIG. 1) and a page buffer (e.g., 35 of FIG. 1).

The circuit elements 220a, 220b and 220c may include, for example, a transistor, but are not limited thereto. For example, the circuit elements 220a, 220b and 220c may further include various passive elements such as resistors and/or inductors as well as various active elements such as transistors and/or diodes. Furthermore although FIG. 1 illustrates that the circuit elements 220a, 220b, and 220c extend in the second direction Y; example embodiments are not limited thereto.

The first interlayer insulating layer 215 may be disposed on the first surface 210a of the peripheral circuit board 210 to cover the circuit elements 220a, 220b and 220c. The first wiring lines 230a, 230b and 230c and the second wiring lines 240a, 240b and 240c may be disposed in the first interlayer insulating layer 215. The first wiring lines 230a, 230b and 230c and the second wiring lines 240a, 240b and 240c may be sequentially disposed on the circuit elements 220a, 220b and 220c. The circuit elements 220a, 220b and 220c may be electrically connected to the first wiring lines 230a, 230b and 230c and the second wiring lines 240a, 240b and 240c. The first interlayer insulating layer 215 may be comprised of a plurality of insulating layers. The number of and/or the arrangement of the first wiring lines 230a, 230b and 230c and the second wiring lines 240a, 240b and 240c, which are shown, are only by way of example and are not limited thereto.

The first interlayer insulating layer 215 may include, for example, an insulating material such as silicon oxide and/or silicon nitride. The first wiring lines 230a, 230b and 230c and the second wiring lines 240a, 240b and 240c may include the same or different conductive materials, for example, one or more of tungsten, aluminum, copper or the like.

Referring to FIGS. 4 and 5, capacitors C1, C2, C3, C4, and C5 are disposed on the second surface 210b of the peripheral circuit board 210. The capacitors C1, C2, C3, C4, and C5 may be disposed throughout the second surface 210b of the peripheral circuit board 210. The capacitors C1, C2, C3, C4, and C5 may overlap or at least partially overlap at least a portion of the circuit elements 220a, 220b, and 220c in the third direction Z.

The first capacitor electrodes 201a, 202a, 203a, 204a, and 205a and the second capacitor electrodes 201b, 202b, 203b, 204b, and 205b may be spaced apart from each other in a direction (for example, the first direction X and/or the second direction Y) horizontal to the second surface 210b of the peripheral circuit board 210. The first capacitor electrodes 201a, 202a, 203a, 204a, and 205a and the second capacitor electrodes 201b, 202b, 203b, 204b, and 205b, which are adjacent to each other, and the capacitor dielectric layer 206 therebetween may constitute or be included in or correspond to the capacitors C1, C2, C3, C4, and C5, e.g., to the plates of the capacitors C1, C2, C3, C4, and C5.

In detail, the capacitor dielectric layer 206 is disposed on the second surface 210b of the peripheral circuit board 210. The first capacitor electrodes 201a, 202a, 203a, 204a, and 205a and the second capacitor electrodes 201b, 202b, 203b, 204b, and 205b are disposed in the capacitor dielectric layer 206. The capacitor dielectric layer 206 covers the first capacitor electrodes 201a, 202a, 203a, 204a, and 205a and the second capacitor electrodes 201b, 202b, 203b, 204b, and 205b. The first capacitor electrodes 201a, 202a, 203a, 204a, and 205a and the second capacitor electrodes 201b, 202b, 203b, 204b, and 205b are not exposed by the capacitor dielectric layer 206.

Different voltages may be applied to the first capacitor electrodes 201a, 202a, 203a, 204a, and 205a and the second capacitor electrodes 201b, 202b, 203b, 204b, and 205b. For example, the first capacitor electrodes 201a, 202a, 203a, 204a, and 205a may be electrically connected to the connection via 214 that passes through the peripheral circuit board 210. The connection via 214 may receive a voltage, for example, from a third input/output pad 309 through the first wiring lines 230a, 230b, and 230c, the second wiring lines 240a, 240b and 240c, and a third input/output contact plug 314. In some example embodiments, the second capacitor electrodes 201b, 202b, 203b, 204b, and 205b may not have a direct electrical connection to any connection via passing through the peripheral circuit board 210.

For example, the first capacitor electrodes 201a, 202a, 203a, 204a and 205a may include (1-1)th to (1-5)th electrodes 201a, 202a, 203a, 204a and 205a that are sequentially stacked along the opposite direction of the third direction Z, and the second capacitor electrodes 201b, 202b, 203b, 204b, and 205b may include (2-1)th to (2-5)th electrodes 201b, 202b, 203b, 204b, and 205b that are sequentially stacked along the opposite direction of the third direction Z. Each of the (1-1)th to (1-5)th electrodes 201a, 202a, 203a, 204a, and 205a and each of the (2-1)th to (2-5)th electrodes 201b, 202b, 203b, 204b, and 205b and the capacitor dielectric layer 206 therebetween may constitute the first to fifth capacitors C1, C2, C3, C4, and C5. At least some capacitances of the first to fifth capacitors C1, C2, C3, C4 and C5 may be different from one another. For example, the capacitances of the first to fifth capacitors C1, C2, C3, C4, and C5 may be ordered in an arithmetic series, or in a geometric series, with one another; example embodiments are not limited thereto.

The capacitor dielectric layer 260 may include a plurality of layers. The number and/or the arrangement of the first capacitor electrodes 201a, 202a, 203a, 204a, and 205a and the second capacitor electrodes 201b, 202b, 203b, 204b, and 205b, which are shown, are only examples, and are not limited thereto.

The capacitor dielectric layer 260 may include an insulating material, and may include, for example, silicon oxide and/or silicon nitride. Alternatively or additionally, the capacitor dielectric layer 260 may include a high-k material having a dielectric constant higher than that of silicon oxide (e.g., aluminum oxide (Al2O3), hafnium oxide (HfO2)).

The first capacitor electrodes 201a, 202a, 203a, 204a, and 205a and the second capacitor electrodes 201b, 202b, 203b, 204b, and 205b may include a conductive material. Each of the first capacitor electrodes 201a, 202a, 203a, 204a, and 205a and the second capacitor electrodes 201b, 202b, 203b, 204b and 205b may independently or concurrently include at least one of tungsten, aluminum, or copper.

The capacitors C1, C2, C3, C4, and C5 may be electrically connected to at least one of the circuit elements 220a, 220b, and 220c through the connection via 214, the first wiring lines 230a, 230b and 230c and the second wiring lines 240a, 240b and 240c. The capacitors C1, C2, C3, C4 and C5 may provide an operating voltage to at least one of the circuit elements 220a, 220b and 220c through the connection via 214, the first wiring lines 230a, 230b and 230c and the second wiring lines 240a, 240b and 240c.

Referring back to FIG. 4, the first insulating film 207 may be disposed on the capacitor dielectric layer 206. The first insulating film 207 may cover the capacitor dielectric layer 206. The first input/output pad 208 may be disposed on the first insulating film 207. The first input/output pad 208 may be electrically connected to at least one of the circuit elements 220a through the first input/output contact plug 212.

The first cell structure CELL1 may include a first cell substrate 310, a plurality of gate electrodes 331 to 338; 330, a second interlayer insulating layer 315, a channel structure CH, a plurality of gate contact plugs 340 including gate contact plugs 341 to 347, a source layer 320, first wiring lines 350a, 350b and 350c, second wiring lines 360a, 360b and 360c, first bonding metals 370a, 370b and 370c, a second insulating film 307, second and third input/output pads 308 and 309, and second and third input/output contact plugs 312 and 314.

The peripheral circuit board 210 and the first cell substrate 310 may be or may include or be included in, for example, one or more of a silicon substrate, a germanium substrate, a silicon-germanium substrate, a silicon-on-insulator (SOI) substrate or a germanium-on-insulator (GOI) substrate.

The memory cell array (20 of FIG. 1), which includes a plurality of memory cells, may be disposed on the bit line bonding area BLBA of the first cell structure CELL1. In some example embodiments, the memory cells included in the first cell structure CELL1 may be nonvolatile memory cells.

For example, the channel structure CH, the gate electrodes 330, and a bit line 360c may be disposed on the first cell substrate 310 of the bit line bonding area BLBA. In the following description, a surface of the first cell substrate 310 on which the memory cell array is disposed may be referred to as a front side. On the contrary, a surface of the first cell substrate 310, which is opposite to the front side of the first cell substrate 310, may be referred to as a back side of the first cell substrate 310. The gate electrodes 330 may be disposed on the front side of the first cell substrate 310. The gate electrodes 330 may have a layered structure extended in parallel with the front side of the first cell substrate 310. The gate electrodes 330 may be sequentially stacked on the first cell substrate 310 by being spaced apart from each other by the second interlayer insulating layer 315. The gate electrodes 330 may be stacked in a stepped shape in the word line bonding area WLBA of the first cell structure CELL1.

For example, the gate electrode 331 may be provided as the ground selection line (GSL of FIG. 2), the gate electrode 338 may be provided as the string selection line (SSL of FIG. 2), and the gate electrodes 332 to 337 may be provided as the word lines (WL11 to WL1n and WL21 to WL2n of FIG. 2).

Each of the gate electrodes 330 may include a conductive material, for example, one or more of a metal such as tungsten (W), cobalt (Co) and nickel (Ni), or a semiconductor material such as silicon, but is not limited thereto.

The second interlayer insulating layer 315 may be disposed on the front side of the first cell substrate 310 to cover the gate electrodes 330. The second interlayer insulating layer 315 may be composed of a plurality of insulating layers. The second interlayer insulating layer 315 may include, for example, at least one of silicon oxide, silicon oxynitride or a low-k material having a dielectric constant lower than that of silicon oxide, but is not limited thereto.

The channel structures CH may be disposed on the first cell substrate 310 of the bit line bonding area BLBA. The channel structures CH may be extended in the third direction Z to pass through the gate electrodes 330. For example, the channel structure CH may have a pillar shape (for example, a cylindrical shape) extended in the third direction Z. Therefore, the channel structure CH may cross the gate electrodes 330.

In some example embodiments, the channel structures CH may be arranged in a zigzag shape. For example, the channel structures CH may be arranged to be alternate with each other in the first direction X and the second direction Y. In some example embodiments, the channel structures CH may be arranged in a honeycomb shape.

Referring to FIG. 6, the channel structure CH may include a semiconductor pattern 130 and an information storage layer 132.

The semiconductor pattern 130 may be extended in the third direction Z to pass through the gate electrodes 330. Although the semiconductor pattern 130 is shown as having only a cup shape, this is only example, and the semiconductor pattern 130 may have various shapes such as a cylindrical shape, a quadrangular barrel shape and a filled pillar shape. The semiconductor pattern 130 may include, for example, a semiconductor material such as monocrystalline silicon such as doped or undoped monosilicon, polycrystalline silicon such as doped or undoped polysilicon, an organic semiconductor material and a carbon nanostructure, but is not limited thereto.

The information storage layer 132 may be interposed between the semiconductor pattern 130 and each of the gate electrodes 330. For example, the information storage layer 132 may be extended along an outer side of the semiconductor pattern 130. In some example embodiments, the information storage layer 132 may be formed of a multi-layer. For example, the information storage layer 132 may include a tunnel insulating layer 132a, a charge storage layer 132b and a blocking insulating layer 132c, which are sequentially stacked on the outer side of the semiconductor pattern 130.

Each of the tunnel insulating layer 132a and the blocking insulating layer 132c may include, for example, silicon oxide and/or a high-k material (e.g., aluminum oxide (Al2O3) and/or hafnium oxide (HfO2)) having a dielectric constant higher than that of silicon oxide. The charge storage layer 132b may include, for example, silicon nitride.

In some example embodiments, the channel structure CH may further include a filling pattern 134. For example, the channel structure CH may be provided with a channel hole extended in the third direction Z to pass through the gate electrodes 330. The information storage layer 132, the semiconductor pattern 130 and the filling pattern 134 may be sequentially stacked in the channel hole. Each of the information storage layer 132 and the semiconductor pattern 130 may be extended to be conformal along a profile of the channel hole. The filling pattern 134 may fill an area of the channel hole, which remains after being filled with the information storage layer 132 and the semiconductor pattern 130.

In some example embodiments, the channel structure CH may further include a channel pad. The channel pad may be electrically connected with an upper portion of the semiconductor pattern 130.

In some example embodiments, the source layer 320 may be interposed between the first cell substrate 310 and the gate electrodes 330. For example, the source layer 320 may be extended to be conformal along the front side of the first cell substrate 310. In some example embodiments, the source layer 320 may be formed on the bit line bonding area BLBA and the word line bonding area WLBA, and may not be formed on the external pad bonding area PA.

The source layer 320 may be connected to the semiconductor pattern 130 of each channel structure CH. For example, the source layer 320 may be in contact with sides of the semiconductor pattern 130 by passing through the information storage layer 132. The source layer 320 may be provided as the common source line (e.g., CSL of FIG. 2) of the semiconductor memory device. The source layer 320 may include, for example, polysilicon doped with impurities and/or metal, but is not limited thereto.

In some example embodiments, a support layer 322 may be disposed on the source layer 320. The support layer 322 may be interposed between the first cell substrate 310 and the source layer 320.

Referring to FIG. 7, in some example embodiments, as shown in A1, the channel structure CH may not include a bending portion. In some example embodiments, as shown in A2, the channel structure CH may include a bending portion. For example, the channel structure CH may include a lower channel LCH and an upper channel UCH, which are connected to each other. A width of the lower channel LCH may be greater than that of the upper channel UCH at a boundary between the lower channel LCH and the upper channel UCH. The channel structure CH may have a bending portion at the boundary between the lower channel LCH and the upper channel UCH. For example, the gate electrodes 332 and 333 forming the boundary between the lower channel LCH and the upper channel UCH may be dummy word lines. Data may not be stored in the memory cells connected to the dummy word line. A voltage level applied to the dummy word line may be different from (e.g., greater than or less than) a voltage level applied to a general word line. The number of the gate electrodes 331 and 332 through which the shown lower channel LCH passes and/or the number of the word lines 333 to 338 through which the upper channel UCH passes are only example, and are not limited thereto.

Referring back to FIG. 4, the first wiring line 350c and the second wiring line 360c may be sequentially disposed on the channel structure CH and thus electrically connected to the channel structure CH. For example, the first wiring line 350c may be electrically connected to the semiconductor pattern (130 of FIG. 6) of the channel structure CH. The second wiring line 360c may be electrically connected to the channel structure CH through the first wiring line 350c. The second wiring line 360c may be provided as the bit line (BL of FIG. 2). The second wiring lines 360c may be extended in the second direction Y, and may be arranged along the first direction X by being spaced apart from each other.

In the bit line bonding area BLBA, the first bonding metal 370c of the first cell structure CELL1 may be electrically connected with the first bonding metal 270c of the peripheral circuit structure PERI by a bonding method. The second wiring line 360c may be electrically connected with the peripheral circuit structure PERI through the first bonding metal 370c and the first bonding metal 270c. For example, a portion of the circuit elements 220c may provide a page buffer, and the second wiring line 360c may be electrically connected to the circuit elements 220c, which provide a page buffer, through the first bonding metal 370c and the first bonding metal 360c.

In the word line bonding area WLBA, the gate contacts 340 may be electrically connected to the gate electrodes 330. For example, each of the gate contacts 340 may be extended in the third direction Z on the gate electrodes 330 and thus electrically connected to the corresponding gate electrodes 330. The first wiring line 350b and the second wiring line 360b may be sequentially disposed on the gate contacts 340 and thus electrically connected to the gate contacts 340.

In the word line bonding area WLBA, the first bonding metal 370b of the first cell structure CELL1 may be electrically connected with the first bonding metal 270b of the peripheral circuit structure PERI by a bonding method. The gate contacts 340 may be electrically connected with the peripheral circuit structure PERI through the first bonding metal 370b and the first bonding metal 270b. For example, a portion of the circuit elements 220b may provide a row decoder, and the gate contacts 340 may be electrically connected to the circuit elements 220b, which provide the row decoder, through the first bonding metal 370b and the first bonding metal 270b.

In the external pad bonding area PA, a source contact plug 380 may be electrically connected to the source layer 320. For example, the source contact plug 380 may be extended in the third direction Z on the source layer 320 and thus electrically connected to the corresponding source layer 320. The first wiring line 350a and the second wiring line 360a may be sequentially disposed on the source contact plug 380 and thus electrically connected to the source contact plug 380.

In the external pad bonding area PA, the first bonding metal 370a of the first cell structure CELL1 may be electrically connected with the first bonding metal 270a of the peripheral circuit structure PERI by a bonding method. The source contact plug 380 may be electrically connected to the peripheral circuit structure PERI through the first bonding metal 370a and the first bonding metal 270a.

The second insulating film 307 may be disposed on the back side of the first cell substrate 310. The second insulating film 307 may cover the back side of the first cell substrate 310. The second and third input/output pads 308 and 309 may be disposed on the second insulating film 307. The second and third input/output contact plugs 312 and 314 may be electrically connected to the peripheral circuit structure PERI through the first bonding metal 370a and the first bonding metal 270a. The second input/output pad 308 may be electrically connected to at least one of the circuit elements 220a through the second input/output contact plug 312. The third input/output pad 309 may be electrically connected to the first capacitor electrodes 201a, 202a, 203a, 204a and 205a through the third input/output contact plug 314 and the connection via 214.

In the semiconductor memory device according to some example embodiments, capacitors C1, C2, C3, C4, and C5 are disposed on the second surface 210b of the peripheral circuit board 210 not the first surface 210a of the peripheral circuit board 210 in which the circuit elements 220a, 220b and 220c are disposed. The capacitors C1, C2, C3, C4, and C5 may not be disposed only in a specific area of the peripheral circuit board 210 but be disposed throughout the bit line bonding area BLBA, the word line bonding area WLBA and the external pad bonding area PA. Therefore, the semiconductor memory device having a reduced size and/or an improved integration may be provided using the second surface 210b of the peripheral circuit board 210 as compared with the case that the capacitors C1, C2, C3, C4, and C5 are formed on the first surface 210a of the peripheral circuit board 210.

FIGS. 8 to 10 are views illustrating a capacitor electrode of a semiconductor memory device according to some example embodiments.

Referring to FIGS. 4 and 8, in the semiconductor memory device according to some example embodiments, at least a portion of the first capacitor electrodes 201a, 202a, 203a, 204a, and 205a and the second capacitor electrodes 201b, 202b, 203b, 204b and 205b may include an extension portion 20a extended in a random direction. The extension portion 20a may have a line shape extended in the random direction. For example, the extension portion 20a may be extended in a direction parallel with the second surface 210b of the peripheral circuit board 210.

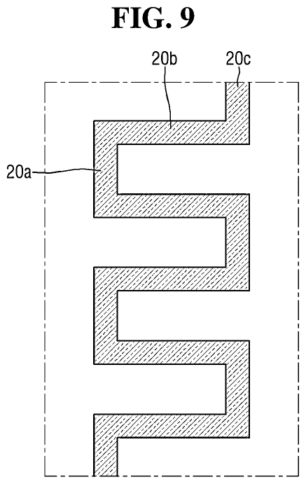

Referring to FIGS. 4 and 9, in the semiconductor memory device according to some example embodiments, at least a portion of the first capacitor electrodes 201a, 202a, 203a, 204a, and 205a and the second capacitor electrodes 201b, 202b, 203b, 204b, and 205b may include first extension portions 20a and 20c extended in a first random direction and a second extension portion 20b extended in a second random direction. For example, the first random direction and the second random direction may be parallel with the second surface 210b of the peripheral circuit board 210, and may be perpendicular to each other. The second extension portion 20b may be arranged in the second random direction. The first extension portion 20a may be connected to one end of the second extension portion 20b, and the first extension portion 20c may be connected to the other end of the second extension portion 20b. The first extension portion 20a, the second extension portion 20b and the first extension portion 20c may be continuously disposed in due order and connected to one another. In some example embodiments, an area, e.g., a surface area, of the first extension portions 20a and 20c, and an area, e.g., a surface area, of the second extension portion 20b may be increased, which may affect a capacitance of at least one of the first capacitor electrodes 201a, 202a, 203a, 204a, and 205a and the second capacitor electrodes 201b, 202b, 203b, 204b, and 205b.

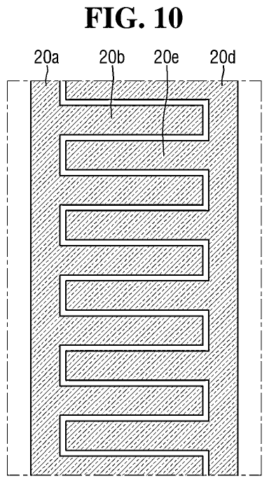

Referring to FIGS. 4 and 10, in the semiconductor memory device according to some example embodiments, at least some of the first capacitor electrodes 201a, 202a, 203a, 204a and 205a and the second capacitor electrodes 201b, 202b, 203b, 204b and 205b may be adjacent to each other in a direction parallel with the second surface 210b of the peripheral circuit board 210, and may have a comb shape. In some example embodiments, a capacitance may be affected by or at least partly determined by the comb shape.

For example, the (1-1)th electrode 201a may include a first extension portion 20a extended in the first random direction and a second extension portion 20b extended in the second random direction, and the (2-1)th electrode 201b may include a first extension portion 20d extended in the first random direction and a second extension portion 20e extended in the second random direction. The second extension portion 20b of the (1-1)th electrode 201a and the second extension portion 20e of the (1-2)th electrode 201b may be alternately arranged in the first random direction.

Each of the electrodes, which are disposed on the same metal layer, among the first capacitor electrodes 201a, 202a, 203a, 204a and 205a and the second capacitor electrodes 201b, 202b, 203b, 204b and 205b may have any one of the shapes of the capacitor electrodes of FIGS. 8 to 10. The electrodes, which are disposed on different metal layers, among the first capacitor electrodes 201a, 202a, 203a, 204a and 205a and the second capacitor electrodes 201b, 202b, 203b, 204b and 205b may have the same shape or may have different shapes.

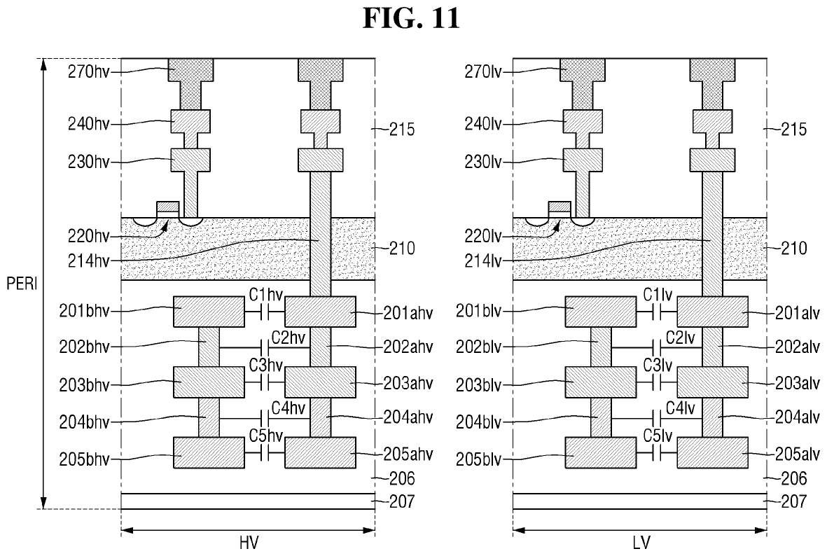

FIG. 11 are views illustrating a semiconductor memory device according to some example embodiments. For convenience of description, redundant portions of those described above with reference to FIGS. 1 to 10 will be briefly described or omitted.

Referring to FIG. 11, the peripheral circuit structure PERI according to some example embodiments may include a high voltage area HV and a low voltage area LV. An operating voltage of a high voltage circuit element 220hv disposed in the high voltage area HV may be different from an operating voltage of a low voltage circuit element 220lv disposed in the low voltage area LV. The operating voltage of the high voltage circuit element 220hv disposed in the high voltage area HV may be relatively higher than (e.g., higher in absolute value than) the operating voltage of the low voltage circuit element 220lv disposed in the low voltage area LV.

In the semiconductor memory device according to some example embodiments, high voltage capacitors C1hv, C2hv, C3hv, C4hv, and C5hv and low voltage capacitors C1lv, C2lv, C31v, C4lv, and C5lv may be formed on the second surface 210b of the peripheral circuit board 210.

First capacitor electrodes 201ahv, 202ahv, 203ahv, 204ahv, and 205ahv and second capacitor electrodes 201bhv, 202bhv, 203bhv, 204bhv, and 205bhv may be disposed in the capacitor dielectric layer 206. Different voltages may be applied to the first capacitor electrodes 201ahv, 202ahv, 203ahv, 204ahv, and 205ahv and the second capacitor electrodes 201bhv, 202bhv, 203bhv, 204bhv, and 205bhv. For example, the first capacitor electrodes 201ahv, 202ahv, 203ahv, 204ahv and 205ahv may receive the voltages through a connection via 214hv passing through the peripheral circuit board 210.

Each of the (1-1)th to (1-5)th electrodes 201ahv, 202ahv, 203ahv, 204ahv, and 205ahv, each of the (2-1)th to (2-5)th electrodes 201bhv, 202bhv, 203bhv, 204bhv, and 205bhv and the capacitor dielectric layer 206 therebetween may constitute each of the first to fifth high voltage capacitors C1hv, C2hv, C3hv, C4hv and C5hv. The capacitances of the high voltage capacitors C1hv, C2hv, C3hv, C4hv, and C5hv may be different from one another. For example, the capacitances of the high voltage capacitors C1hv, C2hv, C3hv, C4hv, and C5hv may be arranged to be in an arithmetic series, or a geometric series, with one another.

The high voltage capacitors C1hv, C2hv, C3hv, C4hv and C5hv may provide operating voltages to the high voltage circuit element 220hv through the connection via 214hv, a first wiring line 230hv and a second wiring line 240hv. A first bonding metal 270hv may be disposed on the second wiring line 240hv.

First capacitor electrodes 201alv, 202alv, 203alv, 204alv and 205alv and second capacitor electrodes 201blv, 202blv, 203blv, 204blv and 205blv may be disposed in the capacitor dielectric layer 206. Different voltages may be applied to the first capacitor electrodes 201alv, 202alv, 203alv, 204alv and 205alv and the second capacitor electrodes 201blv, 202blv, 203blv, 204blv and 205blv. For example, the first capacitor electrodes 201alv, 202alv, 203alv, 204alv and 205alv may receive the voltages through a connection via 214lv passing through the peripheral circuit board 210.

Each of the (1-1)th to (1-5)th electrodes 201alv, 202alv, 203alv, 204alv, and 205alv, each of the (2-1)th to (2-5)th electrodes 201blv, 202blv, 203blv, 204blv, and 205blv and the capacitor dielectric layer 206 therebetween may constitute each of the first to fifth low voltage capacitors C1lv, C2lv, C3lv, C4lv, and C5lv. The capacitances of the low voltage capacitors C1lv, C21v, C3lv, C4lv, and C5lv may be different from one another. For example, the capacitances of the low voltage capacitors C1lv, C2lv, C3lv, C4lv, and C5lv may be ordered to be in an arithmetic series, or a geometric series, with one another.

The low voltage capacitors C1lv, C21v, C3lv, C4lv and C5lv may provide operating voltages to the low voltage circuit element 220lv through the connection via 214lv, a first wiring line 230lv and a second wiring line 240lv. The first bonding metal 2701v may be disposed on the second wiring line 2401v.

The first capacitor electrodes 201ahv, 202ahv, 203ahv, 204ahv, and 205ahv, the second capacitor electrodes 201bhv, 202bhv, 203bhv, 204bhv, and 205bhv, the first capacitor electrodes 201alv, 202alv, 203alv, 204alv, and 205alv and the second capacitor electrodes 201blv, 202blv, 203blv, 204blv, and 205blv may respectively have the shape described above with reference to FIGS. 8 to 10.

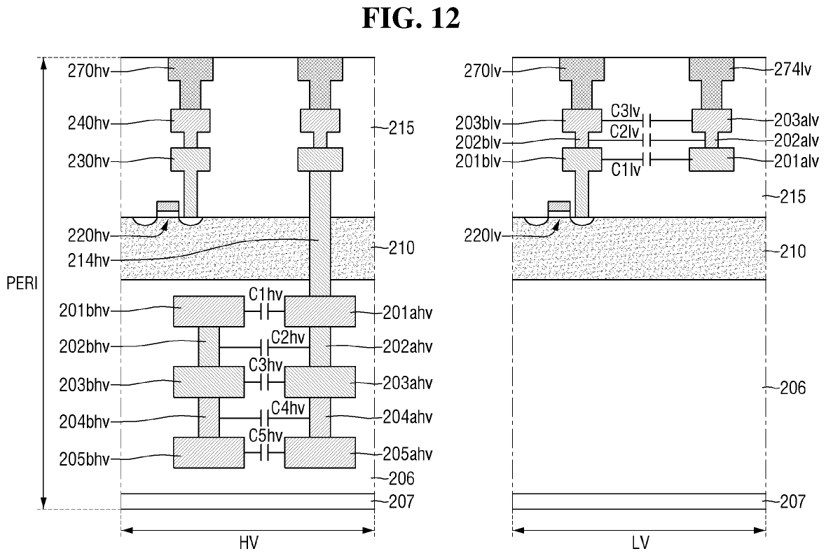

FIG. 12 are views illustrating a semiconductor memory device according to some example embodiments. For convenience of description, redundant portions of those described above with reference to FIG. 11 will be briefly described or omitted.

Referring to FIG. 12, in the semiconductor memory device according to some example embodiments, the high voltage capacitors C1hv, C2hv, C3hv, C4hv and C5hv are formed on the second surface 210b of the peripheral circuit board 210, but the low voltage capacitors C1lv, C2lv and C3lv may be formed on the first surface 210a of the peripheral circuit board 210.

The first capacitor electrodes 201alv, 202alv and 203alv and the second capacitor electrodes 201blv, 202blv and 203blv may be disposed in the first interlayer insulating layer 215. Different voltages may be applied to the first capacitor electrodes 201alv, 202alv and 203alv and the second capacitor electrodes 201blv, 202blv and 203blv. For example, the first capacitor electrodes 201alv, 202alv and 203alv may receive the voltages through the first bonding metal 2701v.

Each of the (1-1)th to (1-3)th electrodes 201alv, 202alv, and 203alv, each of the (2-1)th to (2-3)th electrodes 201blv, 202blv, and 203blv and the capacitor dielectric layer 206 therebetween may constitute each of the first to third low voltage capacitors C1lv, C2lv, and C31v. The capacitances of the low voltage capacitors C1lv, C2lv and C3lv may be different from one another. For example, each of the (1-1)th to (1-3)th electrodes 201alv, 202alv and 203alv may be formed on the same metal layer as each of a first wiring line in the first interlayer insulating layer 215, a via of the second wiring line in the first interlayer insulating layer 215 and a wiring of the second wiring line in the first interlayer insulating layer 215.

The low voltage capacitors C1lv, C21v, C3lv may provide operating voltages to the low voltage circuit element 220lv through the first and second wiring lines in the first interlayer insulating layer 215. The first bonding metal 270lv may be disposed on the (1-3)th electrode 203alv. The first bonding metal 270lv may be disposed on the (2-3)th electrode 203blv.

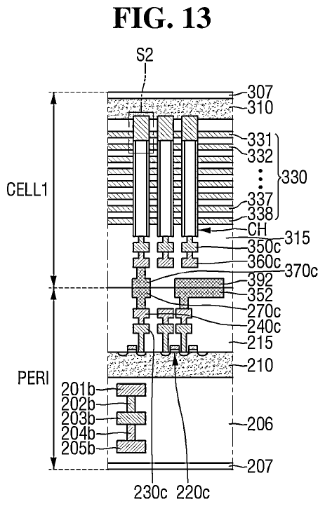

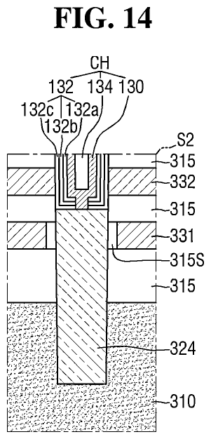

FIG. 13 is a cross-sectional view illustrating a semiconductor memory device according to some example embodiments. FIG. 14 is an enlarged view illustrating an area S1 of FIG. 13. For convenience of description, redundant portions of those described above with reference to FIGS. 1 to 12 will be briefly described or omitted.

Referring to FIGS. 13 and 14, the semiconductor memory device according to some example embodiments may include a source pattern 324.

The source pattern 324 may be formed on the first cell substrate 310. The source pattern 324 may be connected to the semiconductor pattern 130 of the channel structure CH. For example, the semiconductor pattern 130 may be in contact with an upper surface of the source pattern 324 by passing through the information storage layer 132. The source pattern 324 and the first cell substrate 310 may be provided as the common source line (CSL of FIG. 2) of the semiconductor memory device. A lower portion of the source pattern 324 is shown as being only embedded in the first cell substrate 310, but this is only example. As another example, a lower surface of the source pattern 324 may be disposed on the front side and a coplanar surface of the first cell substrate 310.

The source pattern 324 may include a conductive material, for example, polysilicon doped with impurities or metal, but is not limited thereto. The source pattern 324 may be formed by, for example, a selective epitaxial growth process from the first cell substrate 310, but is not limited thereto.

In some example embodiments, the upper surface of the source pattern 324 may cross a portion of the gate electrodes 330. For example, the upper surface of the source pattern 324 may be higher than that of the gate electrode 331. In this case, a gate insulating film 315S may be interposed between the gate electrode (e.g., the gate electrode 331) crossing the source pattern 324 and the source pattern 324.

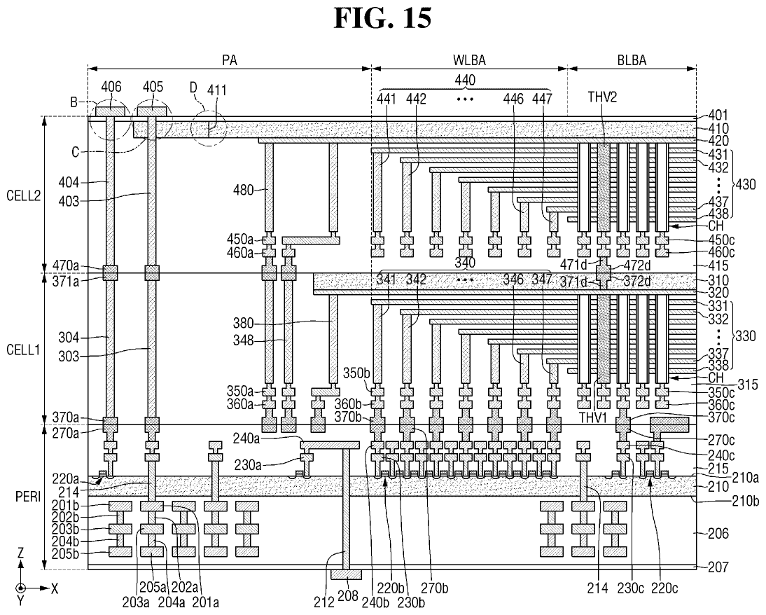

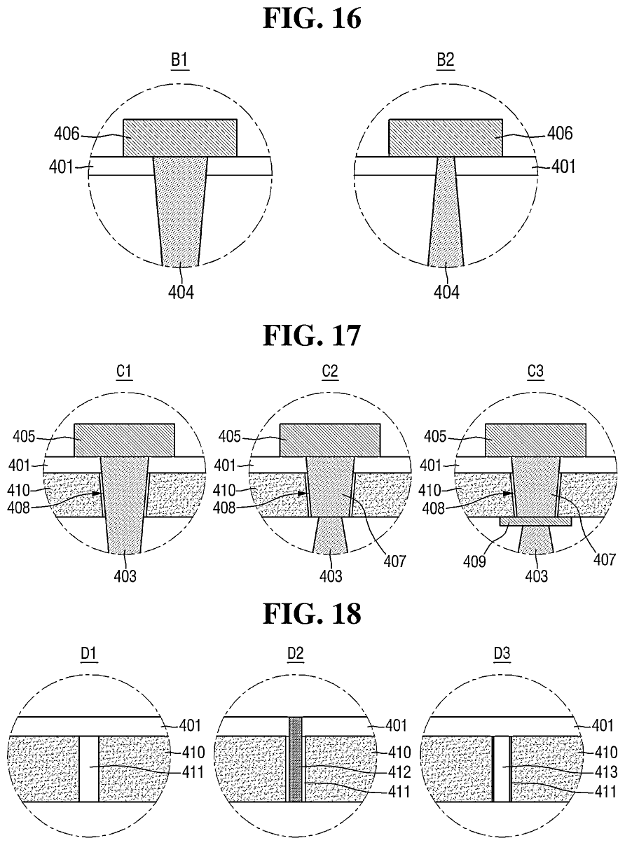

FIG. 15 is a cross-sectional view illustrating a semiconductor memory device according to some example embodiments. FIG. 16 is an enlarged view illustrating an area B of FIG. 15. FIG. 17 is an enlarged view illustrating an area C of FIG. 15. FIG. 18 is an enlarged view illustrating an area D of FIG. 15. For convenience of description, redundant portions of those described above with reference to FIGS. 1 to 14 will be briefly described or omitted.

Referring to FIG. 15, the semiconductor memory device according to some example embodiments may include a plurality of cell structures CELL1 and CELL2 in which the memory cell array (20 of FIG. 1) including memory cells is disposed. For example, the second cell structure CELL2 may be stacked on the first cell structure CELL1. The structure of the second cell structure CELL2 in the regions other than the periphery region PA may be the same as, or different from, the structure of the first cell structure CELL1. Hereinafter, an upper portion, an upper surface, a lower portion and a lower surface of the second cell structure CELL2 are defined based on the opposite direction of the third direction Z, but this is only example. Only one of the first upper chip and the second upper chip may be inverted and connected in a bonding manner.

The second cell structure CELL2 includes a second cell substrate 410, a plurality of gate electrodes 430 including gate electrodes 431 to 438, which may or may not be the same number in the plurality of gate electrodes 330, a third interlayer insulating layer 415, a channel structure CH, a plurality of gate contacts 441 to 447; 440, a source layer 420, first wiring lines 450a, 450b, and 450c, second wiring lines 460a, 460b and 460c, first bonding metals 470a, 470b, and 470c, a second insulating film 401, second and third input/output pads 405 and 406, and second and third input/output contact plugs 403 and 404.

The memory cell array (20 of FIG. 1) including a plurality of memory cells may be disposed on the bit line bonding area BLBA of the second cell structure CELL2. For example, the channel structure CH, the gate electrodes 430 and the bit line 460c may be disposed on the second cell substrate 410 of the bit line bonding area BLBA. In the following description, a surface of the second cell substrate 410 on which the memory cell array is disposed may be referred to as a front side. On the contrary, a surface of the second cell substrate 410, which is opposite to the front side of the second cell substrate 410, may be referred to as a back side of the second cell substrate 410.

The gate electrodes 430 may be disposed on the front side of the second cell substrate 410. The third interlayer insulating layer 415 may be disposed on the front side of the second cell substrate 410 to cover the gate electrodes 430. The channel structure CH may be disposed on the second cell substrate 410 of the bit line bonding area BLBA. The source layer 420 may be disposed between the second cell substrate 410 and the gate electrodes 430. The first wiring line 450c and the second wiring line 460c may be sequentially disposed on the channel structure CH and thus electrically connected to the channel structure CH. The second wiring line 460c may be provided as the bit line (BL of FIG. 2).

The gate electrodes 430, the third interlayer insulating layer 415, the channel structure CH of the second cell structure CELL2, the source layer 420, the first wiring line 450c and the second wiring line 460c may be the same as or similar to the gate electrodes 330, the second interlayer insulating layer 315, the channel structure CH of the first cell structure CELL1, the source layer 320, the first wiring line 350c and the second wiring line 360c in their shapes and structures.

In the bit line bonding area BLBA, a first through electrode THV1 may be disposed in the first cell structure CELL1, and a second through electrode THV2 may be disposed in the second cell structure CELL2. The first through electrode THV1 may pass through the source layer 320 and the gate electrodes 330, but this is only an example. The first through electrode THV1 may further pass through the first cell substrate 310. The first through electrode THV1 may include a conductive material. Alternatively, the first through electrode THV1 may include a conductive material surrounded by an insulating material. The second through electrode THV2 may have the same shape and structure as those of the first through electrode THV1.

In some example embodiments, the first through electrode THV1 and the second through electrode THV2 may be electrically connected to each other through a first through metal pattern 372d and a second through metal pattern 472d. A first via 371d may be disposed between the first through electrode THV1 and the first through metal pattern 372d, and a second via 471d may be disposed between the second through electrode THV2 and the second through metal pattern 472d. The first through metal pattern 372d and the second through metal pattern 472d may be connected to each other by a bonding method.

In the word line bonding area WLBA, the gate contacts 440 may be electrically connected to the gate electrodes 430. The gate contacts 440 may be electrically connected to the peripheral circuit structure PERI through a cell contact plug 348.

In the external pad bonding area PA, a source contact plug 480 may be electrically connected to the source layer 420. The first wiring line 450a and the second wiring line 460a may be sequentially disposed on the source contact plug 480 and thus electrically connected to the source contact plug 480.

The second insulating film 401 may be disposed on the back side of the second cell substrate 410. The second insulating film 401 may cover the back side of the second cell substrate 410. The second and third input/output pads 405 and 406 may be disposed on the second insulating film 401. The second input/output pad 405 may be electrically connected to at least one of the circuit elements 220a of the peripheral circuit structure PERI through the second input/output contact plugs 403 and 303, and the third input/output pad 406 may be electrically connected to at least one of the circuit elements 220a of the peripheral circuit structure PERI through the third input/output contact plugs 404 and 304. The connection via 214 may receive a voltage through, for example, the second input/output contact plugs 403 and 303 or the third input/output contact plugs 404 and 304.

In some example embodiments, the third input/output contact plug 404 may be separated from the second cell substrate 410 in a direction parallel with the front side of the second cell substrate 410, and may be electrically connected to the third input/output pad 406 by passing through the third interlayer insulating layer 145 of the second cell structure CELL2.

Referring to FIG. 16, as shown in B1, the third input/output contact plug 404 may be extended in the third direction Z, and its diameter may be increased toward the second insulating film 401. For example, as shown in B2, the third input/output contact plug 404 may be extended in the third direction Z, and its diameter may be reduced toward the second insulation film 401.

Referring to FIG. 17, in some example embodiments, the second input/output contact plug 403 may be electrically connected to the second input/output pad 405 through the second cell substrate 410.

For example, as shown in C1, an opening 408 passing through the second cell substrate 410 is formed, and the second input/output contact plug 403 may be directly connected to the second input/output pad 405 through the opening 408 formed in the second cell substrate 410. Illustratively, as shown in C2, a contact 407 may be formed in the opening 408. One end of the contact 407 may be connected to the second input/output pad 405, and the other end thereof may be connected to the second input/output contact plug 403. For example, as shown in C3, a stopper 409 may be further formed on an upper surface of the opening 408 of the second cell substrate 410 unlike C2. The stopper 409 may be a metal line formed on the same layer as the source layer 420, but this is only example. The stopper 409 may be a metal line formed on the same layer as at least one of the gate electrodes 430.

According to the embodiments, a slit 411 may be formed in the second cell substrate 410. For example, the slit 411 may be formed at any position of the external pad bonding area PA. Referring to FIG. 18, for example, as shown in D1, the slit 411 may be formed to pass through the second cell substrate 410. For example, as shown in D2, a conductive material 412 may be formed in the slit 411. For example, as shown in D3, an insulating material 413 may be formed in the slit 411.

According to various example embodiments, the first to third input/output pads 205, 405 and 406 may be selectively formed. For example, the semiconductor memory device may include at least one of the first to third input/output pads 205, 405 or 406.

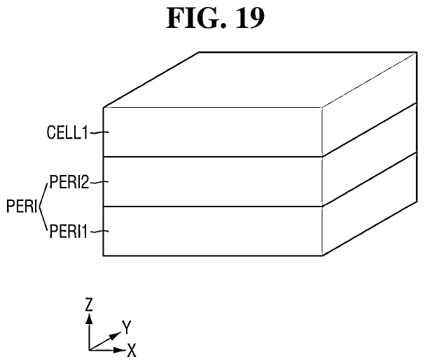

FIG. 19 is a schematic perspective view illustrating a semiconductor memory device according to some example embodiments. For convenience of description, redundant portions of those described above with reference to FIGS. 1 to 14 will be briefly described or omitted.

Referring to FIG. 19, in the semiconductor memory device according to some example embodiments, the peripheral circuit structure PERI may include a first peripheral circuit structure PERI1 and a second peripheral circuit structure PERI2. The first peripheral circuit structure PERI1, the second peripheral circuit structure PERI2 and the first cell structure CELL1 are stacked in the third direction Z.

A portion of the peripheral circuit structure (PERI of FIGS. 1 to 14) may be disposed in the first peripheral circuit structure PERI1, and the other portion thereof may be disposed in the second peripheral circuit structure PERI2.

In some example embodiments, the peripheral circuit board 210, the capacitors C1, C2, C3, C4, and C5 and the circuit elements 220a, 220b and 220c, which are electrically connected to the capacitors C1, C2, C3, C4, and C5, of FIGS. 1 to 14 may be disposed in the first peripheral circuit structure PERI1. The second peripheral circuit structure PERI2 may include a peripheral circuit board and circuit elements 220a, 220b and 220c, which are not electrically connected to the capacitors C1, C2, C3, C4 and C5, on the peripheral circuit board.

In some example embodiments, the peripheral circuit board 210, the capacitors C1, C2, C3, C4, and C5 and the circuit elements 220a, 220b and 220c, which are electrically connected to the capacitors C1, C2, C3, C4, and C5, of FIGS. 1 to 14 may be disposed in the second peripheral circuit structure PERI2. The first peripheral circuit structure PERI1 may include a peripheral circuit board and circuit elements 220a, 220b and 220c, which are not electrically connected to the capacitors C1, C2, C3, C4, and C5, on the peripheral circuit board.

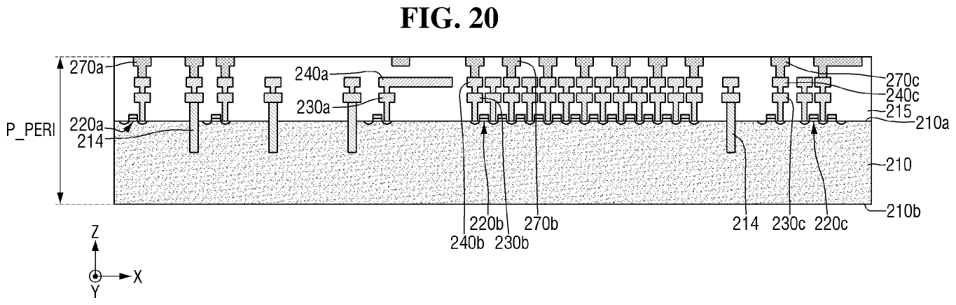

FIGS. 20 to 22 are views illustrating intermediate steps to describe a method for fabricating a semiconductor memory device according to some example embodiments. For convenience of description, redundant portions of those described above with reference to FIGS. 1 to 14 will be briefly described or omitted.

Referring to FIG. 20, a pre-peripheral circuit structure P_PERI is formed.

The pre-peripheral circuit structure P_PERI includes a peripheral circuit board 210, circuit elements 220a, 220b and 220c, a connection via 214, first wiring lines 230a, 230b and 230c, second wiring lines 240a, 240b and 240c, first bonding metals 270a, 270b and 270c and a first interlayer insulating layer 215.

The peripheral circuit board 210 may include a first surface 210a and a second surface 210b, which are opposite to each other. The circuit elements 220a, 220b and 220c and the connection via 214 are formed on the first surface 210a of the peripheral circuit board 210. A portion of the connection via 214 is formed in the peripheral circuit board 210. For example, the connection via 214 may pass through a portion of the peripheral circuit board 210. The first wiring lines 230a, 230b and 230c, the second wiring lines 240a, 240b and 240c and first bonding metals 270a, 270b and 270c are formed on the connection via 214 and the peripheral circuit board 210. The first interlayer insulating layer 215 is formed on the first surface 210a of the peripheral circuit board 210. The circuit elements 220a, 220b and 220c, the connection via 214, the first wiring lines 230a, 230b and 230c, the second wiring lines 240a, 240b and 240c and the first bonding metals 270a, 270b and 270c are formed in the first interlayer insulating layer 215. Upper surfaces of the first bonding metals 270a, 270b and 270c may be exposed by the first interlayer insulating layer 215.

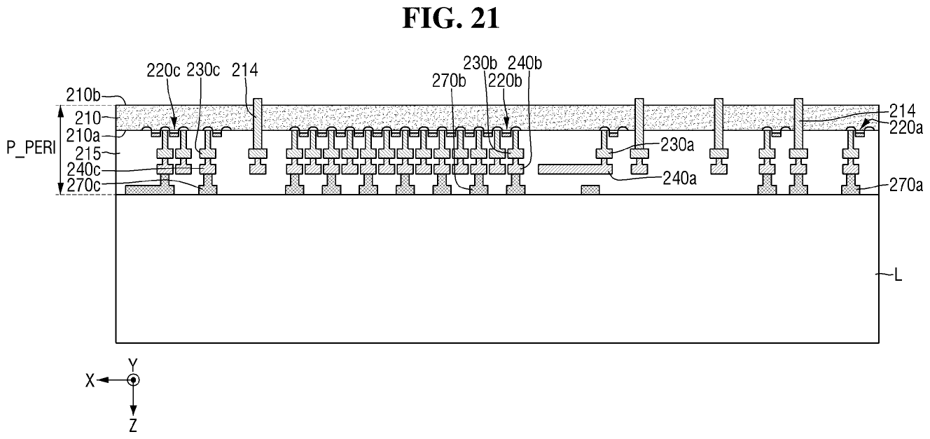

Referring to FIG. 21, the pre-peripheral circuit structure P_PERI of FIG. 20 is bonded onto a semiconductor chip L. The first surface 210a of the peripheral circuit board 210 may be bonded to the semiconductor chip L such that the first surface 210a of the peripheral circuit board 210 is oriented toward the semiconductor chip L.

For example, the semiconductor chip L may include a bonding metal, and the semiconductor chip L and the pre-peripheral circuit structure P_PERI may be bonded to each other by bonding between the bonding metal and the first bonding metals 270a, 270b and 270c.

In some example embodiments, the semiconductor chip L may be the first cell structure CELL1 of FIG. 3. For example, the semiconductor chip L may include memory cells.

In some example embodiments, the semiconductor chip L may be a dummy wafer or dummy chip or dummy die, e.g., a wafer or a chip or a die without any electrically active components and/or a blank wafer or chip or die. In this case, after the peripheral circuit structure PERI is formed, the semiconductor chip L may be removed, and the peripheral circuit structure PERI and the first cell structure CELL1 may be bonded to each other.

Subsequently, a portion of the peripheral circuit board 210 is removed so that a portion of the connection via 214 is exposed. A portion of the connection via 214 may protrude toward the outside. For example, grinding, chemical mechanical polishing or etch back may be performed for the second surface 210b of the peripheral circuit board 210, so that the connection via 214 may be exposed.

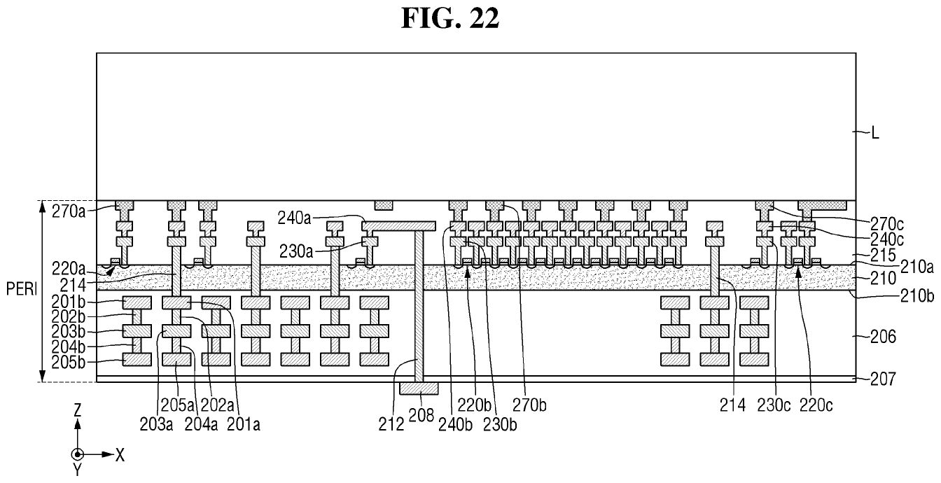

Referring to FIG. 22, a capacitor electrically connected to the connection via 214 is formed on the second surface 210b of the peripheral circuit board 210.

The first capacitor electrodes 201a, 202a, 203a, 204a, and 205a, the second capacitor electrodes 201b, 202b, 203b, 204b, and 205b and the capacitor dielectric layer 206 are formed on the second surface 210b of the peripheral circuit board 210. The first capacitor electrodes 201a, 202a, 203a, 204, a and 205a and the second capacitor electrodes 201b, 202b, 203b, 204b, and 205b are formed in or inside the capacitor dielectric layer 206 and thus are not exposed to the outside. The first capacitor electrodes 201a, 202a, 203a, 204a and 205a are formed on the connection via 214. The first insulating film 207, the first input/output pad 208 and the first input/output contact plug 212 are formed so that the peripheral circuit structure PERI is formed.

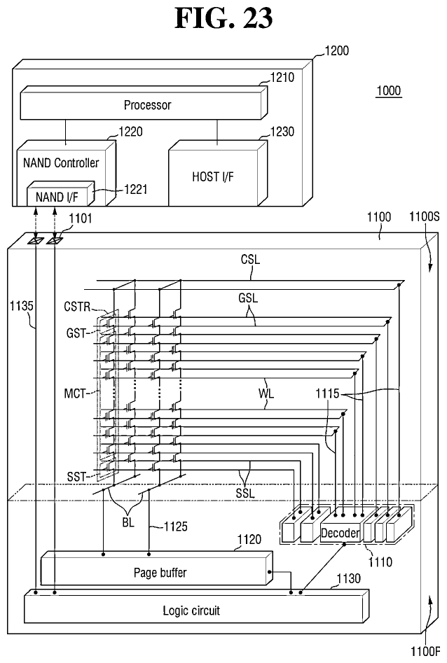

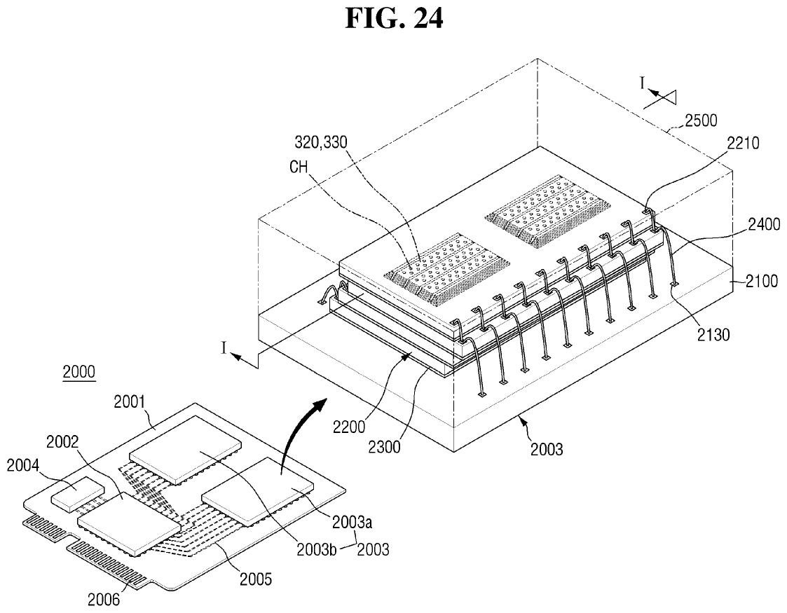

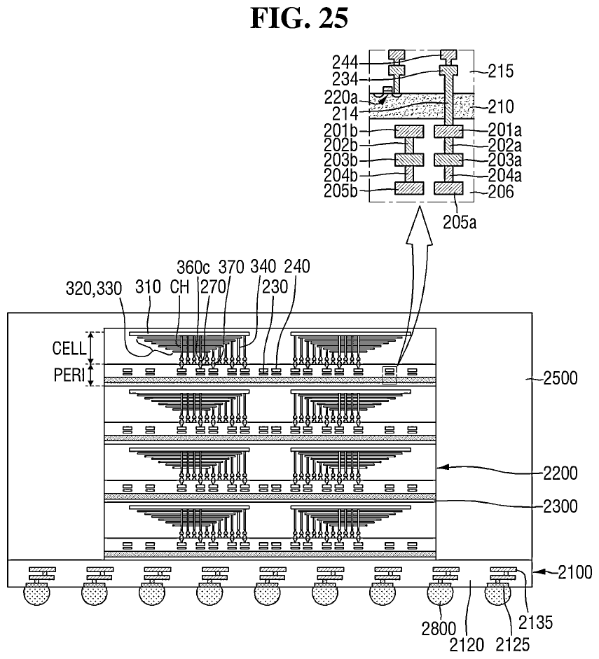

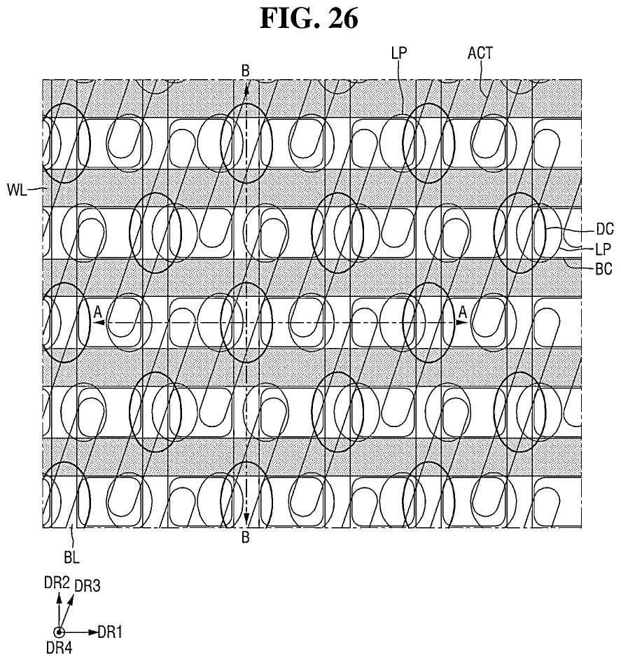

FIG. 23 is an example block diagram illustrating an electronic system according to some example embodiments. FIG. 24 is an example perspective view illustrating an electronic system according to some example embodiments. FIG. 25 is a schematic cross-sectional view taken along line I-I of FIG. 24. For convenience of description, redundant portions of those described above with reference to FIGS. 1 to 14 will be briefly described or omitted.

Referring to FIG. 23, an electronic system 1000 according to some example embodiments may include a semiconductor memory device 1100 and a controller 1200 electrically connected to the semiconductor memory device 1100. The electronic system 1000 may be a storage device including one or a plurality of semiconductor memory devices 1100 or an electronic device including the storage device. For example, the electronic system 1000 may be or may include or be included in one or more of a solid state drive (SSD) device, a universal serial bus (USB), a computing system, a medical device or a communication device, which includes one or more semiconductor memory devices 1100.

The semiconductor memory device 1100 may be a nonvolatile memory device (e.g., NAND flash memory device), and may be, for example, the semiconductor memory device described with reference to FIGS. 1 to 14. The semiconductor memory device 1100 may include a first structure 1100F and a second structure 1100S on the first structure 1100F.

The first structure 1100F may be a peripheral circuit structure that includes a decoder circuit 1110 (e.g., the row decoder 33 of FIG. 1), a page buffer 1120 (e.g., the page buffer 35 of FIG. 1) and a logic circuit 1130 (e.g., the control logic 37 of FIG. 1). For example, the first structure 1100F may correspond to the peripheral circuit structure PERI described with reference to FIGS. 1 to 13.

The second structure 1100S may include a common source line CSL, a plurality of bit lines BL, and a plurality of cell strings CSTR, which are described above with reference to FIG. 2. The cell strings CSTR may be connected to the decoder circuit 1110 through a word line WL, at least one string selection line SSL and at least one ground selection line GSL. In addition, the cell strings CSTR may be connected to the page buffer 1120 through the bit lines BL. For example, the second structure 1100S may correspond to the first cell structure CELL1 described with reference to FIGS. 1 to 13.

In some example embodiments, the common source line CSL and the cell strings CSTR may be electrically connected to the decoder circuit 1110 through first connection lines 1115 extended from the first structure 1100F to the second structure 1100S. For example, the first connection line 1115 may correspond to the gate contacts 340 described with reference to FIGS. 1 to 13. For example, the gate contacts 340 may electrically connect the gate electrodes 330 with the decoder circuit 1110 (e.g., the row decoder 33 of FIG. 1).

In some example embodiments, the bit lines BL may be electrically connected to the page buffer 1120 through second connection lines 1125. For example, the second connection line 1125 may correspond to the first wiring line 350c described with reference to FIGS. 1 to 13. For example, the first wiring line 350c may electrically connect the bit lines BL with the page buffer 1120 (e.g., the page buffer 35 of FIG. 1).

The semiconductor memory device 1100 may perform communication with the controller 1200 through an input/output pad 1101 electrically connected to the logic circuit 1130 (e.g., the control logic 37 of FIG. 1). The input/output pad 1101 may be electrically connected to the logic circuit 1130 through an input/output connection line 1135 extended from the first structure 1100F to the second structure 1100S. For example, the connection line 1135 may correspond to the second and third input/output contact plugs 312 and 314 described with reference to FIGS. 1 to 13.

The controller 1200 may include a processor 1210, a NAND controller 1220 and a host interface 1230. In some example embodiments, the electronic system 1000 may include a plurality of semiconductor memory devices 1100, and in this case, the controller 1200 may control the plurality of semiconductor memory devices 1100.

The processor 1210 may control some or all, such as the overall operation of the electronic system 1000 including the controller 1200. The processor 1210 may operate in accordance with predetermined firmware, and may access the semiconductor memory device 1100 by controlling the NAND controller 1220. The NAND controller 1220 may include a NAND interface 1221 that processes communication with the semiconductor memory device 1100. A control command for controlling the semiconductor memory device 1100, data to be written in the memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 24 and 25, an electronic system 2000 according to some example embodiments may include a main board 2001, a main controller 2002 packaged on the main board 2001, one or more semiconductor packages 2003 and a DRAM 2004. The semiconductor package 2003 and the DRAM 2004 may be connected to the main controller 2002 by wiring patterns 2005 formed in the main board 2001.

The main board 2001 may include a connector 2006 that includes a plurality of pins coupled to the external host. The number and arrangement of the plurality of pins in the connector 2006 may be varied depending on the communication interface between the electronic system 2000 and the external host. In some example embodiments, the electronic system 2000 may perform communication with the external host in accordance with any one or more of interfaces such as a Universal Serial Bus (USB), a Peripheral Component Interconnect Express (PCI-Express), Serial Advanced Technology Attachment (SATA) and M-Phy for Universal Flash Storage (UFS). In some example embodiments, the electronic system 2000 may operate by a power source supplied from the external host through the connector 2006. The electronic system 2000 may further include a power management integrated circuit (PMIC) that distributes the power source supplied from the external host to the main controller 2002 and the semiconductor package 2003.

The main controller 2002 may write data in the semiconductor package 2003 or read the data from the semiconductor package 2003, and may improve the operating speed of the electronic system 2000.

The DRAM 2004 may be a buffer memory for mitigating a speed difference between the semiconductor package 2003 that is a data storage space and the external host. Also, the DRAM 2004 included in the electronic system 2000 may operate as a kind of a cache memory, and may provide a space for temporarily storing data in a control operation for the semiconductor package 2003. When the DRAM 2004 is included in the electronic system 2000, the main controller 2002 may further include a DRAM controller for controlling the DRAM 2004, in addition to the NAND controller for controlling the semiconductor package 2003.

The semiconductor package 2003 may include a first semiconductor package 2003a and a second semiconductor package 2003b, which are spaced apart from each other. Each of the first semiconductor package 2003a and the second semiconductor package 2003b may be a semiconductor package that includes a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on lower surfaces of the respective semiconductor chips 2200, a connection structure 2400 for electrically connecting the semiconductor chips 2200 with the package substrate 2100, and a molding layer 2500 covering the semiconductor chips 2200 and the connection structure 2400 on the package substrate 2100.

The package substrate 2100 may be a printed circuit board that includes package upper pads 2130. Each semiconductor chip 2200 may include an input/output pad 2210. The input/output pad 2210 may correspond to the input/output pad 1101 of FIG. 23.

In some example embodiments, the connection structure 2400 may be a bonding wire for electrically connecting the input/output pad 2210 with the package upper pads 2130. Therefore, in each of the first semiconductor package 2003a and the second semiconductor package 2003b, the semiconductor chips 2200 may be electrically connected to each other in a bonding wire manner, and may be electrically connected to the package upper pads 2130 of the package substrate 2100. In some example embodiments, in each of the first semiconductor package 2003a and the second semiconductor package 2003b, the semiconductor chips 2200 may be electrically connected to each other by a connection structure that includes a through silicon via (TSV), instead of or in addition to the connection structure 2400 of the bonding wire manner.

In some example embodiments, the main controller 2002 and the semiconductor chips 2200 may be included in one package. In some example embodiments, the main controller 2002 and the semiconductor chips 2200 may be packaged on a separate interposer substrate different from the main board 2001, and the main controller 2002 may be connected with the semiconductor chips 2200 by a wire formed in the interposer substrate.

In some example embodiments, the package substrate 2100 may be a printed circuit board. The package substrate 2100 may include a package substrate body portion 2120, package upper pads 2130 disposed on an upper surface of the package substrate body portion 2120, lower pads 2125 disposed on a lower surface of the package substrate body portion 2120 or exposed through the lower surface, and internal wires 2135 electrically connecting the upper pads 2130 with the lower pads 2125 inside the package substrate body portion 2120. The upper pads 2130 may be electrically connected to the connection structures 2400. The lower pads 2125 may be connected to the wiring patterns 2005 of the main board 2001 of the electronic system 2000 through conductive connectors 2800 as shown in FIG. 24.

In the electronic system according to some example embodiments, each of the semiconductor chips 2200 may include the semiconductor memory device described with reference to FIGS. 1 to 13. For example, each of the semiconductor chips 2200 may include a peripheral circuit structure PERI, and a first cell structure CELL stacked on the peripheral circuit structure PERI. Illustratively, the peripheral circuit structure PERI may include first capacitor electrodes 201a, 202a, 203a, 204a, and 205a, second capacitor electrodes 201b, 202b, 203b, 204b and 205b and a capacitor dielectric layer 206, which are disposed on the back side 210b of the peripheral circuit board 210, and the peripheral circuit structure PERI and the first cell structure CELL1 may be bonded to each other through first bonding metals 270 including bonding metals 270a, 270b and 270c and second bonding metals 370 including bonding metals 370a, 370b and 370c.

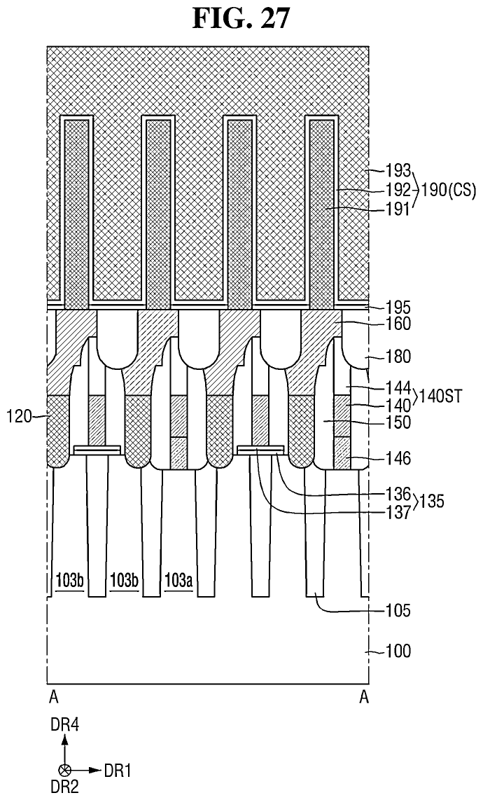

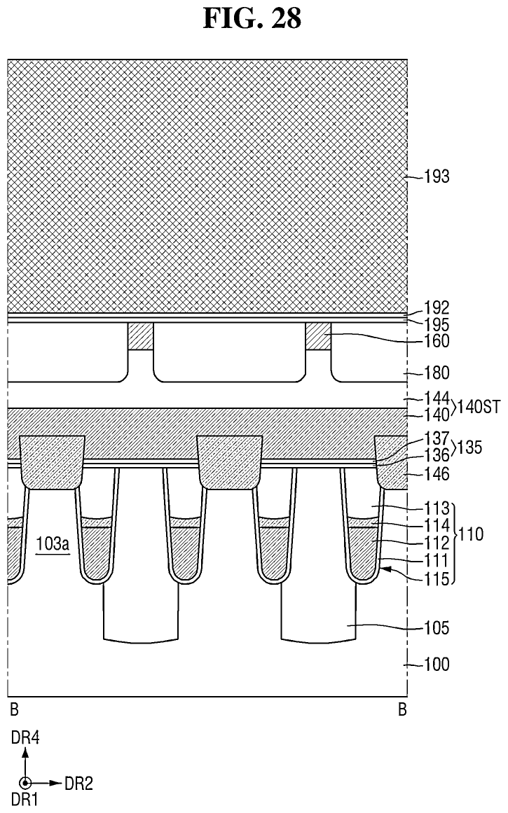

FIGS. 26 to 28 are views illustrating a semiconductor memory device according to some example embodiments. FIG. 27 is a cross-sectional view taken along line A-A of FIG. 26, and FIG. 28 is a schematic cross-sectional view taken along line B-B of FIG. 26.

Referring to FIGS. 26 to 28, in the semiconductor memory device according to some example embodiments, memory cells included in the first cell structure CELL1 of FIG. 3 may be volatile memory cells.

Referring to FIG. 26, a substrate (100 of FIGS. 27 and 28) may include a plurality of active areas ACT. The active area ACT may be defined by an element isolation layer (105 of FIGS. 27 and 28) formed in the substrate 100. For example, the active area ACT may be extended in the third direction DR3.

A plurality of gate electrodes extended in the first direction DR1 may be disposed across the active area ACT. The plurality of gate electrodes may be extended in parallel with each other. The plurality of gate electrodes may be, for example, a plurality of word lines WL.

Each active area ACT may be divided into three portions by two word lines WL extended in the first direction DR1. The active area ACT may include a storage connection area 103b and a bit line connection area 103a. The bit line connection area 103a may be positioned at a center portion of the active area ACT, and the storage connection area 103b may be positioned at the end of the active area ACT. For example, the bit line connection area 103a may be an area connected to the bit line BL, and the storage connection area 103b may be an area connected to a capacitor structure 190. For example, the bit line connection area 103a may correspond to a common drain area, and the storage connection area 103b may correspond to a source area. Each word line WL, and the bit line connection area 103a and the storage connection area 103b, which are adjacent to each word line WL, may constitute a transistor.

A plurality of bit lines BL extended in the second direction DR2 perpendicular to the word line WL may be disposed on the word line WL. The plurality of bit lines BL may be extended in parallel with each other.

Referring to FIGS. 27 and 28, the semiconductor memory device according to some example embodiments may include a plurality of gate structures 110, a plurality of bit line structures 140ST, a plurality of bit line contacts 146, and a memory structure such as a memristor and/or capacitor structure 190.

The gate structure 110 may be formed in the substrate 100 and the element isolation layer 105. The gate structure 110 may be formed across the element isolation layer 105 and the active area ACT defined by the element isolation layer 105. The gate structure 110 may include a gate trench 115, a gate insulating film 111, a gate electrode 112, a gate capping pattern 113 and a gate capping conductive film 114. The gate electrode 112 may correspond to the word line (WL of FIG. 26).

The gate insulating film 111 may be extended along sidewalls and a bottom surface of the gate trench 115. The gate electrode 112 may be disposed on the gate insulating film 111. The gate electrode 112 may fill a portion of the gate trench 115. The gate capping conductive layer 114 may be extended along an upper surface of the gate electrode 112. The gate capping pattern 113 may fill the gate trench 115 remaining after the gate electrode 112 and the gate capping conductive layer 114 are formed.

The bit line structure 140ST may include a conductive line 140 and a line capping layer 144. The conductive line 140 may be disposed on the element isolation layer 105 and the substrate 100 in which the gate structure 110 is formed. The conductive line 140 may cross the element isolation layer 105 and the active area ACT. The conductive line 140 may be formed to cross the gate structure 110. The conductive line 140 may correspond to the bit line (BL of FIG. 26). The line capping layer 144 may be disposed on the conductive line 140. A bit line spacer 150 may be disposed on sidewalls of the conductive line 140 and the line capping layer 144.

The bit line contact 146 may be formed between the bit line connection area 103a of the active area ACT and the conductive line 140. The bit line contact 146 may be connected to the bit line connection area 103a. The bit line contact 146 may correspond to a direct contact (DC of FIG. 26).

The plurality of storage contacts 120 may be disposed between the conductive lines 140 adjacent to each other in the first direction DR1. The storage contact 120 may be connected to the storage connection area 103b of the active area ACT. The storage contact 120 may correspond to a buried contact BC.

A storage pad 160 may be disposed on the storage contact 120. The storage pad 160 may be electrically connected to the storage contact 120. The storage pad 160 may correspond to a landing pad LP. A pad isolation insulating layer 180 includes an insulating material, and may electrically isolate a plurality of storage pads 160 from each other. An etch stop film 195 may be disposed on the storage pad 160 and the pad isolation insulating layer 180.

The capacitor structure 190 may be disposed on the storage pad 160. The capacitor structure 190 may be electrically connected to the storage pad 160. The capacitor structure 190 may include a lower electrode 191, a capacitor dielectric film 192 and an upper electrode 193.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Although various example embodiments have been described with reference to the accompanying drawings, it will be apparent to those of ordinary skill in the art that the present disclosure can be fabricated in various forms without being limited to the above-described example embodiments and can be embodied in other specific forms without departing from technical spirits and essential characteristics of inventive concepts. Thus, the above embodiments are to be considered in all respects as illustrative and not restrictive. Furthermore example embodiments are not necessarily mutually exclusive with one another. For example, some example embodiments may include one or more features described with reference to one or more figures, and may also include one or more other features described with reference to one or more other figures.

1. A semiconductor memory device comprising:
a peripheral circuit structure; and
a cell structure on the peripheral circuit structure and including a cell substrate and a gate electrode,
wherein the peripheral circuit structure includes
a peripheral circuit board including a first surface facing the cell structure and a second surface opposite to the first surface,
a first circuit element on the first surface of the peripheral circuit board,
a first interlayer insulating layer covering the first surface of the peripheral circuit board,
a first wiring line electrically connected to the first circuit element in the first interlayer insulating layer,
a capacitor dielectric layer covering the second surface of the peripheral circuit board,
a first capacitor electrode in the capacitor dielectric layer,
a second capacitor electrode spaced apart from the first capacitor electrode in the capacitor dielectric layer, and
a first connection via electrically connecting the first capacitor electrode with the first wiring line by passing through the peripheral circuit board.

2. The semiconductor memory device of claim 1, wherein the first capacitor electrode and the second capacitor electrode are not exposed by the capacitor dielectric layer.

3. The semiconductor memory device of claim 1, wherein the first capacitor electrode and the second capacitor electrode are spaced apart from each other in a direction parallel with the second surface of the peripheral circuit board.

4. The semiconductor memory device of claim 1, wherein
the first capacitor electrode includes (1-1)th to (1-n)th electrodes (where n is a natural number greater than or equal to 2) sequentially stacked on the second surface of the peripheral circuit board, and
the second capacitor electrode includes (2-1)th to (2-n)th electrodes sequentially stacked on the second surface of the peripheral circuit board.

5. The semiconductor memory device of claim 4, wherein at least a portion of the (1-1)th to (1-n)th electrodes and at least a portion of the (2-1)th to (2-n)th electrodes have a line shape extended in a direction parallel with the second surface of the peripheral circuit board.

6. The semiconductor memory device of claim 4, wherein at least a portion of the (1-1)th to (1-n)th electrodes and at least a portion of the (2-1)th to (2-n)th electrodes have a comb shape.

7. The semiconductor memory device of claim 4, wherein at least a portion of the (1-1)th to (1-n)th electrodes and at least a portion of the (2-1)th to (2-n)th electrodes includes,
a first extension portion extending in a first direction parallel with the second surface of the peripheral circuit board, and
a second extension portion extending in a second direction parallel with the second surface of the peripheral circuit board and crossing the first direction.

8. The semiconductor memory device of claim 1, wherein the peripheral circuit structure further includes,
a second circuit element on the first surface of the peripheral circuit board,
a second wiring line electrically connected to the second circuit element in the first interlayer insulating layer,
a third capacitor electrode in the capacitor dielectric layer,
a fourth capacitor electrode spaced apart from the third capacitor electrode in the capacitor dielectric layer, and
a second connection via electrically connecting the third capacitor electrode with the second wiring line by passing through the peripheral circuit board, wherein
the second circuit element is configured to operate at an operating voltage different from that of the first circuit element.

9. The semiconductor memory device of claim 1, wherein the peripheral circuit structure includes,
a second circuit element on the first surface of the peripheral circuit board,
a second wiring line electrically connected to the second circuit element in the first interlayer insulating layer,
a third capacitor electrode in the first interlayer insulating layer, and
a fourth capacitor electrode spaced apart from the third capacitor electrode in the first interlayer insulating layer.

10. The semiconductor memory device of claim 9, wherein the second circuit element is configured to operate at an operating voltage of the second circuit element lower than that of the first circuit element.

11.-12. (canceled)

13. A semiconductor memory device comprising:
a first peripheral circuit structure; and
a cell structure stacked on the first peripheral circuit structure and including memory cells,
wherein the first peripheral circuit structure includes
a first peripheral circuit board including a first surface facing the cell structure and a second surface opposite to the first surface,
a first circuit element on the first surface of the first peripheral circuit board, and
a first capacitor on the second surface of the first peripheral circuit board.

14. The semiconductor memory device of claim 13, wherein the cell structure includes a first bonding metal, and
the first peripheral circuit structure further includes
a second bonding metal bonded to the first bonding metal,
a first wiring line between the first circuit element and the second bonding metal, and
a connection via electrically connecting the first capacitor with the first wiring line by passing through the first peripheral circuit board.

15. The semiconductor memory device of claim 13, wherein the first peripheral circuit structure further includes
second circuit elements on the first surface of the first peripheral circuit board, and
a second capacitor on the first surface of the first peripheral circuit board.

16. The semiconductor memory device of claim 13, wherein the first capacitor includes
a capacitor dielectric layer on the second surface of the first peripheral circuit board,
a first capacitor electrode in the capacitor dielectric layer, and
a second capacitor electrode in the capacitor dielectric layer and spaced apart from the first capacitor electrode in a direction parallel with the second surface of the first peripheral circuit board.

17.-18. (canceled)

19. The semiconductor memory device of claim 13, further comprising:
a second peripheral circuit structure including a second peripheral circuit board and a second circuit element on the second peripheral circuit board,
wherein the second peripheral circuit structure is between the first peripheral circuit structure and the cell structure.

20. The semiconductor memory device of claim 13, further comprising:
a second peripheral circuit structure including a second peripheral circuit board and a second circuit element on the second peripheral circuit board,
wherein the first peripheral circuit structure is between the second peripheral circuit structure and the cell structure.

21. The semiconductor memory device of claim 13, wherein at least some of the memory cells are volatile memory cells.

22. The semiconductor memory device of claim 13, wherein at least some of the memory cells are nonvolatile memory cells.

23. (canceled)

24. An electronic system comprising:
a main board;
a semiconductor memory device on the main board and including a peripheral circuit structure and a cell structure, the cell structure being stacked on the peripheral circuit structure; and
a controller electrically connected to the semiconductor memory device on the main board;
wherein the peripheral circuit structure includes
a peripheral circuit board including a first surface facing the cell structure and a second surface opposite to the first surface,
a first circuit element on the first surface of the peripheral circuit board, and
a capacitor configured to provide an operating voltage to the first circuit element on the second surface of the peripheral circuit board.

25. The electronic system of claim 24, wherein the capacitor includes a capacitor dielectric layer covering the second surface of the peripheral circuit board, first capacitor electrodes stacked in the capacitor dielectric layer, and second capacitor electrodes stacked in the capacitor dielectric layer.

26.-28. (canceled)
